(19) United States
(12) Patent Application Publication
(10) Pub. No.: US 2009/0068824 A1
(43) Pub. Date: Mar. 12, 2009

(54) FABRICATING METHOD OF SEMICONDUCTOR DEVICE

(75) Inventors: Po-Wei Liu, Taichung City (TW); Cheng-Tzung Tsai, Taipei City (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/853,539

(22) Filed: Sep. 11, 2007

(51) Int. Cl. H01L 21/425

(52) U.S. Cl. 438/530; 257/E21.473

(57) ABSTRACT

A method for fabricating a semiconductor substrate is provided. A substrate having a region adjacent to a surface of the substrate as a channel region is provided. An ion implantation process is performed to form an amorphized silicon layer in the substrate below the channel region. A thermal treatment process is performed to re-crystallize the amorphized silicon layer so as to form an epitaxial material layer. The epitaxial material layer may enhance the stress on the channel region in the substrate.

### BACKGROUND OF THE INVENTION

1. Field of Invention

The present invention relates to a fabrication method of a semiconductor device; more particularly, the present invention relates to a fabrication method of a semiconductor substrate in which the process steps are simpler and uncomplicated, film layers are easily developed and defects are minimized.

2. Description of Related Art

In the development of integrated circuit devices, high operating speed and low power consumption are achieved by diminishing the dimensions of the devices. However, there is a limit in which the dimensions of the devices can be further reduced. Moreover, such an approach is costly. Hence, other techniques aside from the miniaturization of device dimensions are being developed to improve the driving current of the devices.

Currently, the industry has provided an alternative approach to surpass the limitation of the technique in reducing the device dimensions by controlling the strain at the channel region of the transistor. According to this approach, an epitaxial layer and a silicon cap layer are sequentially formed on a silicon substrate, wherein the silicon cap layer may serve as a channel region of the transistor device, while the epitaxial layer formed under the silicon cap layer may generate strain at the channel to enhance the mobility of electrons or holes, and to increase the driving current of the device. A structure that relies on strain control to increase the device efficiency is known as a strain transfer structure (STS). For an NMOS (N-type metal oxide semiconductor) transistor, the epitaxial layer underneath the channel region is, for example, a silicon-germanium (SiGe) layer, which can induce tensile strain at the channel region to enhance the mobility of electrons. For a PMOS (P-type metal oxide semiconductor) transistor, the expitaxial layer may be, for example, a silicon-carbon layer, which can induce compressive strain at the channel region to enhance the mobility of holes.

In the above strain transfer structure, the epitaxial material may use for fabricating the source/drain (S/D) region of the transistor device to further enhance the mobility of holes or electrons and to improve the efficiency of the device. For example, a silicon-carbon material may use for the source/drain region of an NMOS transistor, while a silicon-germanium material may use for the source/drain region of a PMOS transistor.

Although the application of the strain transfer structure technique may increase the driving current of a transistor, there are problems remained in this fabrication technique. Currently, the method in forming the epitaxial layer and the silicon cap layer (channel region) in the strain transfer structure is by performing the selective epitaxial growth (SEG) process, in which an epitaxial layer is formed on a silicon substrate, followed by performing a deposition process to form a silicon cap layer on the epitaxial layer. However, the above mentioned selective epitaxial growth (SEG) process is complicated and is difficult to perform well. More particularly, for a PMOS device, it is difficult to grow the silicon-carbon layer by the selective epitaxial growth process and many defects are formed in the resulting layer. Hence, the reliability of the device is compromised, and the driving current of the device is affected and the uniformity of device efficiency is lower.

### SUMMARY OF THE INVENTION

The present invention is to provide a fabrication method of a substrate and a fabrication method of a semiconductor device, wherein the fabrication process is simple and problems regarding difficulties in growing the film and defects being formed in the film can be resolved. Moreover, the mobility of the carriers can be increased to improve the efficiency of the device.

The present invention is to provide a fabrication method of a semiconductor substrate, wherein a substrate is provided and a region in the substrate proximal to the surface of the substrate is designated for forming a channel region. An ion implantation process is then performed to form an amorphized silicon layer in the substrate under the channel region. Thereafter, a thermal process is performed to re-crystallize the amorphized silicon layer to form an epitaxial material layer and to increase the stress in the channel region near the silicon surface.

In accordance to the fabrication method of a semiconductor substrate of the present invention, the ion implantation process includes a pre-amorphization implantation process.

In accordance to the fabrication method of a semiconductor substrate of the present invention. Further, the thermal process includes an anneal process, for example, and the thermal process is conducted at a temperature between 400 to 900 degrees Celsius, and the duration of the thermal process is about 10 seconds to 2 hours.

In accordance to the fabrication method of a semiconductor substrate of the present invention, the above semiconductor substrate is applicable for forming a P-type metal oxide semiconductor transistor and the stress is a compressive stress in the channel region. Further, the dopants used in the ion implantation process are carbon ions, and the dosage is about 10¹⁴˜10¹⁶ cm⁻², and the implantation energy is about 1˜10 keV.

In accordance to the fabrication method of a semiconductor substrate of the present invention, the above semiconductor substrate is applicable for forming an N-type metal oxide semiconductor transistor and the stress is a tensile stress in the channel region. Further, the dopants used in the ion implantation process are germanium ions, and the dosage is about 10¹⁵˜5×10¹⁶ cm⁻² and the implantation energy is about 10˜40 keV

The present invention provides a fabrication method of a semiconductor device, wherein a substrate is provided and a region in the substrate near the surface of the substrate is designated for forming a channel region. An ion implantation process is then performed to form an amorphized silicon layer in the substrate under the channel region. Thereafter, a thermal process is performed to recrystallize the amorphized silicon layer to form a first epitaxial material layer for increasing the stress in the channel region. A gate structure, a spacer on a sidewall of the gate structure and two source/drain regions beside two sides of the gate structure in the substrate are sequentially formed on the substrate, wherein the gate structure includes a gate dielectric layer and a gate conductive layer.

According to an embodiment of the fabrication method of a semiconductor device of the present invention, the ion implantation process includes a pre-amporphization implantation process.

In accordance to the fabrication method of a semiconductor device of the present invention, the thermal process includes an anneal process, wherein the thermal process is conducted at a temperature between 400 to 900 degrees Celsius, and the duration of the treatment is about 10 seconds to 2 hours.

In accordance to the fabrication method of a semiconductor device of the present invention, the above semiconductor substrate is applicable for forming a P-type metal oxide semiconductor transistor and the stress is a compressive stress. Further, the dopants used in the ion implantation process are carbon ions, and the dosage is about 10¹⁴˜10¹⁶ cm⁻²., and the implantation energy is about 1˜10 keV.

In accordance to the fabrication method of a semiconductor device of the present invention, the above semiconductor substrate is applicable for forming an N-type metal oxide semiconductor transistor and the stress is a tensile stress. Further, the dopants used in the ion implantation process are germanium ions, and the dosage is about 10¹⁵˜5×10¹⁶ cm⁻² and the implantation energy is about 10˜40 keV.

In accordance to the fabrication method of a semiconductor device of the present invention, the above-mentioned source/drain regions include a doped region formed in the substrate and a second epitaxial material layer disposed above the doped region. If the semiconductor device is a P-type metal oxide semiconductor transistor device, the second epitaxial material layer is a silicon-germanium layer. If the semiconductor device is an N-type metal oxide semiconductor device, the second epitaxial material layer is a silicon-carbon layer.

In accordance to the fabrication method of a semiconductor device of the present invention, the source/drain region includes an epitaxial material layer formed in the substrate. If the semiconductor device is a P-type metal oxide semiconductor transistor, the epitaxial material layer is a silicon-germanium layer. If the semiconductor device is an N-type metal oxide semiconductor transistor, the epitaxial material layer is a silicon-carbon layer.

In accordance to the fabrication method of a semiconductor device of the present invention, subsequent to forming the semiconductor device, a silicide layer is further formed on the gate structure and the two source/drain regions. The above silicide layer is a heat resistant metal silicide, which may select from the group of nickel, tungsten, cobalt, titanium, molybdenum, and platinum.

In accordance to the fabrication method of a semiconductor device of the present invention, a stress layer is further formed to cover and in conformal to the semiconductor device and the substrate. The material that constitutes the above stress layer includes, for example silicon nitride or silicon oxide. In one embodiment, a doping process or an annealing process may perform on the stress layer to adjust to strain value of the stress layer. If the semiconductor device is a P-type metal oxide semiconductor transistor, the strain layer is a compressive stress layer. If the semiconductor device is an N-type metal oxide semiconductor transistor, the stress layer is a tensile stress layer.

In accordance to the fabrication method of a semiconductor device of the present invention, an ion implantation process and a thermal process are used to replace the conventional SEG process. Hence, an epitaxial material in a substrate may use to increase the stress in the channel region and the mobility of the carriers is increased to improve the efficiency of the device. Further, comparing with the conventional SEG process, the fabrication process of the present invention is simpler and less complicated. Further, the problems with difficulties in growing the silicon-carbon layer by the selective epitaxial growth (SEG) process and defects being formed in the silicon-carbon layer can be obviated.

In order to make the aforementioned and other objects, features and advantages of the present invention comprehensible, a preferred embodiment accompanied with figures is described in detail below.

### BRIEF DESCRIPTION OF THE DRAWINGS

FIGS. 1 to 5 are schematic, cross-section view diagrams showing selected process steps in fabricating a semiconductor device according to one embodiment.

### DESCRIPTION OF EMBODIMENTS

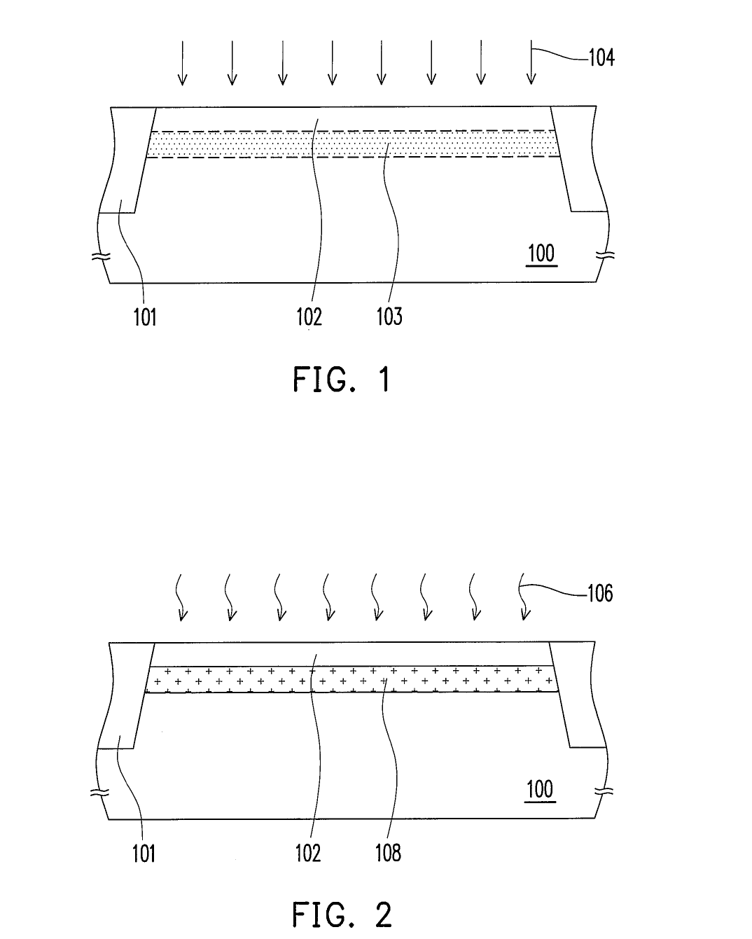

FIGS. 1 to 5 are schematic, cross-section view diagrams showing selected process steps in fabricating a semiconductor device according to one embodiment. In this embodiment, for illustration purposes, the semiconductor device is a P-type metal oxide semiconductor (PMOS) transistor.

Referring to FIG. 1, a substrate 100 is provided, wherein the substrate 100 includes an isolation structure 101 already formed therein. At the substrate 100 proximal to isolation structure, a region 102 predetermined for a channel region is formed therein near the surface of the substrate 100. The isolation structure 101 includes, for example a shallow trench isolation structure or other appropriate isolation structure. The substrate 100 is, for example, a bulk-silicon substrate or a silicon-on-insulator (SOI) substrate. A SOI substrate includes, stacking from bottom to top, for example, a substrate plate, an insulation layer and a semiconductor layer, wherein a material of the substrate plate is, for example, silicon; the material of the insulation layer is, for example, silicon oxide; and a material of the semiconductor layer is selected from a group including but not limited to silicon, epitaxial silicon (epi-Si), germanium, silicon-germanium alloy, and silicon-carbon alloy.

An ion implantation process, for example, a pre-amorphization implant (PAI) is performed on the substrate 100 to amorhpize the silicon lattice of the substrate 100 and to form an amorphized silicon layer 103 in the substrate underneath the region 102. In one embodiment of the invention, the dopants used in the ion implantation process are carbon ions, the implanted dosage is between 10¹⁴ to 10¹⁶ cm⁻², the implantation energy is between about 1 to 10 keV. Moreover, the dopant concentration resulted from the ion implantation process performed on the substrate 100 increases from the surface of the substrate 100 to the interior of the substrate 100.

In another embodiment, prior to performing the ion implantation process 104, a sacrificial layer is formed (not shown) to cover the substrate 100. This sacrificial layer is used to protect the substrate 100 from damages being induced on the surface thereof due to the ion implantation process 104. A material that may use to constitute the sacrificial layer includes, but not limited to, silicon oxide, which is formed by thermal oxidation, for example. Moreover, subsequent to the ion implantation process 104, the sacrificial layer is removed.

Referring to FIG. 2, a thermal treatment process, for example, an annealing process, is performed to re-crystallize the amorphized silicon layer 103 to form an epitaxial material layer 108 for increasing the stress on the channel region 102. The thermal treatment process 106 is performed at 400 to 900 degrees Celsius and the duration of the treatment is about 10 seconds to 2 hours. In one embodiment of the present invention, the epitaxial material layer is a silicon-carbon layer, which can increase the compressive stress in the channel region 102.

In another embodiment, if the semiconductor device is an N-type metal oxide semiconductor (NMOS) transistor, the dopants used in the ion implantation process 104 include germanium ions, the implanted dosage is about 10¹⁵˜5×10¹⁶ cm⁻², and the implantation energy is about 10˜40 keV. Further, when the epitaxial material layer 108 is a silicon-germanium layer, the tensile stress in the channel region is increased.

It is worthy to note that the epitaxial material layer formed in the substrate is fabricated by an ion implantation process and a thermal treatment process. Hence, the stress in the channel region is increased and the mobility of the carriers is correspondingly enhanced to improve the efficiency of the device. Accordance to the conventional approach, the epitaxial material layer is formed by a selective epitaxial growth (SEG) process, followed by depositing an additional silicon layer on the epitaxial material layer to serve as the channel region. Hence, the fabrication method of the present invention, in comparison to the conventional SEG process, is simpler and less complicated, and the problems with difficulties in growing the silicon-carbon layer by the selective epitaxial growth process and defects forming in the silicon-carbon layer can be obviated.

Further, in other embodiments, after completing the thermal treatment process 106, a selective epitaxial growth process may be performed to form a cap layer on the substrate 100 (not shown). The cap layer and the channel region 102 together serve as the channel layer.

After completing the fabrication of a semiconductor substrate that can provide higher carrier mobility and improved device efficiency, the fabrication of other components of the semiconductor device may proceed.

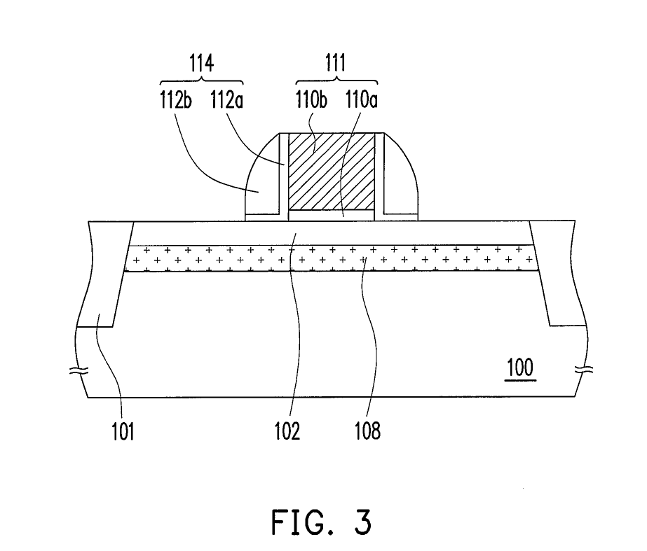

Thereafter, as shown in FIG. 3, a dielectric layer (not shown) and a conductive layer (not shown) are sequentially formed on the substrate 100. A patterning process is then performed to define the conductive layer and the dielectric layer to form a gate conductive layer 110b and the gate dielectric layer 110a as a gate structure 111. A material that constitutes the gate conductive layer 110b includes but not limited to doped polysilicon, metal, or other appropriate conductive materials. The gate dielectric layer 110a includes, for example, silicon oxide, silicon nitride or silicon oxynitride, or other high dielectric constant dielectric layer materials, such as aluminum oxide (Al₂O₃), yttrium oxide (Y₂O₃), zirconium silicon oxide (ZrSiₓO_{y}), hafnium silicon oxide (HfSiₓO_{y}), lanthanum sesquioxide (La₂O₃), zirconium dioxide (ZrO₂), hafnium dioxide (HfO₂), tantalum pentoxide (Ta₂O₅), praseodymium oxide (Pr₂O₃) or titanium dioxide (TiO₂).

Then, a spacer 114 is formed on a sidewall of the gate structure 111. The spacer 114 includes a combination of an offset spacer 112a and a silicon nitride spacer 112b. A material used in forming the offset spacer 112a includes, for example, silicon oxide/silicon oxide, silicon oxide/silicon nitride, silicon oxide/silicon oxide/silicon nitride, silicon oxide/silicon nitride/silicon oxide, silicon oxide/silicon nitride/silicon oxide/silicon nitride/silicon oxide or other appropriate materials.

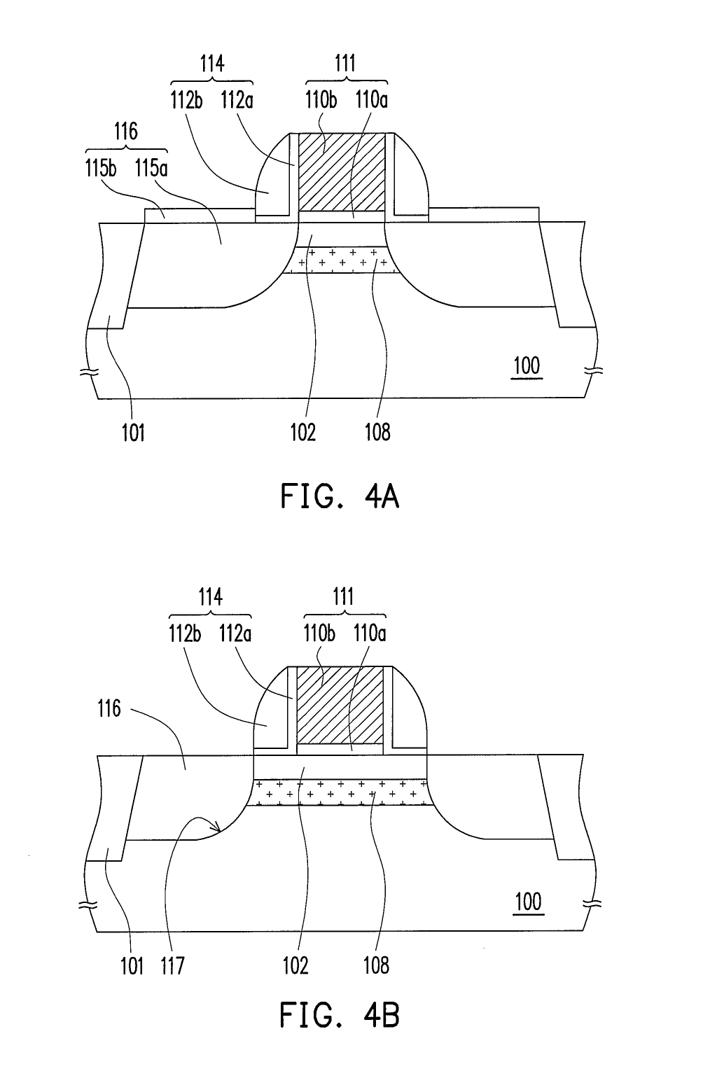

Continuing to FIGS. 4A and 4B, two source/drain regions 116 are formed in the substrate 100 beside two sides of the gate structure 111. As shown in FIG. 4A, the two source/drain regions 116 are formed by, for example, performing an ion implantation process to form a doped region 115a in the substrate 100 beside two sides of the gate structure 111. Subsequent to the formation of the doped region 115a, an epitaxial material layer 115b is formed to cover the doped region 115a, wherein the doped region 115a and the epitaxial material layer 115 serve as a source/drain region 116, for example, a raised source/drain region. In an embodiment of the invention for P-type metal oxide semiconductor (PMOS) transistor, the epitaxial material layer 115b is silicon-carbon layer. Moreover, as shown in FIG. 4B, the source/drain region 116 may be an epitaxial material layer in the substrate 100, which is formed by forming a trench 117 in the substrate 100 by removing a portion of the substrate 100 at the two sides of the spacer 106, followed by forming the epitaxial material layer in the trench 117. In this embodiment, the epitaxial material layer is, for example a silicon-germanium layer. In another embodiment, if the semiconductor device is an N-type metal oxide semiconductor (NMOS) transistor, the epitaxial material layer 115b in FIG. 4A and the epitaxial material layer (source/drain region 116) in FIG. 4B are a silicon-germanium and silicon-carbon layer, respectively.

According to the above fabrication method in forming the source/drain region of the semiconductor device with an epitaxial material layer, the carrier mobility is enhanced and the device efficiency is increased.

Thereafter, a silicide layer (not shown) is formed on the top part of the gate structure 111 and the surface of the source/drain region 116 to lower the resistance of the device. The silicide layer includes heat resistant metal silicide such as, nickel, tungsten, cobalt, titanium, molybdenum, and platinum.

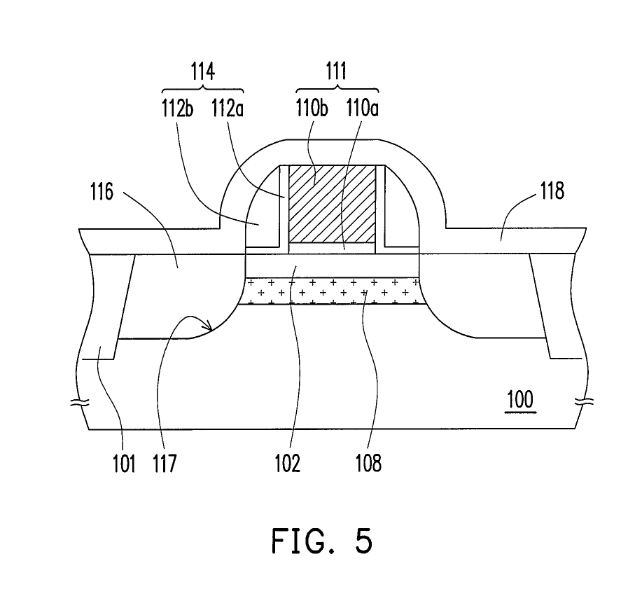

Referring to FIG. 5, after the fabrication of the semiconductor device is completed, a stress layer 118 is formed to cover the entire substrate 100 to increase the driving current and efficiency of the device. In this embodiment, the formation of a stress layer on the structure shown in FIG. 4B is described as an example. The material of the stress layer 118 may be silicon nitride, for example, and is formed by low pressure chemical vapor deposition. The material of the stress layer 118 may also be silicon oxide. Moreover, a doping process or an annealing process may perform on the stress layer 118 to adjust the stress value. For example, the stress value is lowered by performing a doping process on the stress layer 118, whereas the stress value is raised by performing an annealing process on the stress layer 118. In this embodiment, the stress layer 118 is a compressive stress layer. In another embodiment, if the semiconductor device is an N-type metal oxide semiconductor (NMOS) transistor, the stress layer 118 is a tensile stress layer.

Further, it is worthy to note that, the present invention is also applicable in a complementary semiconductor device, for example, a complementary metal oxide semiconductor (CMOS) transistor. Since people skilled in the art are familiar with the fundamentals of a complementary semiconductor device, the fabrication of a complementary semiconductor device in accordance to the present invention is readily accessible based on the disclosure above and will not be further reiterated herein.

According to the method of the present invention, the stress in the channel region is increased by the epitaxial layer in the substrate. Hence, the mobility of the carriers is enhanced and the efficiency of the device is increased. Moreover, the process of the invention, in comparison with the conventional SEG process, is simpler and less complicated. Additionally, the problems regarding difficulties in growing a silicon-carbon layer by the selective epitaxial growth process and defects being formed in the silicon-carbon layer can be obviated.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method of fabricating a semiconductor substrate, comprising:
providing a substrate, wherein the substrate comprises a region proximal to a surface of the substrate, and the region is designated for forming a channel region;
performing an ion implantation process to form a amorphized layer in the substrate underneath the channel region; and
performing a thermal treatment process to re-crystallize the amorphized layer to form an epitaxial layer to enhance a stress in the channel region.

2. The method of claim 1, wherein the ion implantation process includes a pre-amorphization implantation process.

3. The method of claim 1, wherein the thermal process includes an annealing process.

4. The method of claim 1, wherein the thermal treatment process is conducted at a temperature of about 400˜900 degrees Celsius.

5. The method of claim 1, wherein the thermal treatment process is conducted for about 10 seconds to 2 hours.

6. The method of claim 1, wherein the semiconductor substrate is applicable for a P-type metal oxide semiconductor transistor, and the stress is a compressive stress.

7. The method of claim 6, wherein dopants used in the ion implantation process include carbon ions.

8. The method of claim 6, wherein a dosage of dopants used in ion implantation process is about 10¹⁴˜10¹⁶ cm⁻².

9. The method of claim 6, wherein implantation energy of the ion implantation process is about 1˜10 keV.

10. The method of claim 1, wherein the semiconductor substrate is applicable for an N-type metal oxide semiconductor transistor, and the stress is a tensile stress.

11. The method of claim 10, wherein dopants used in the ion implantation process include germanium ions.

12. The method of claim 10, wherein a dosage of dopants used in ion implantation process is about 10¹⁵˜5×10¹⁶ cm⁻².

13. The method of claim 10, wherein implantation energy of the ion implantation process is about 10˜40 keV.

14. A fabrication method of a semiconductor device, the method comprising:
providing a substrate, wherein the substrate comprises a region, which is predetermined in forming a channel region, proximal to a surface of the substrate;
performing an ion implantation process to form a amorphized layer in the substrate underneath the channel region;
performing a thermal treatment process to re-crystallize the amorphized layer to form a first epitaxial material layer in order to enhance a stress in the channel region; and forming a gate structure on the substrate, a spacer on a sidewall of the gate structure and two source/drain regions in the substrate at two sides of the gate structure, wherein the gate structure includes a gate dielectric layer and a gate conductive layer.

15. The method of claim 14, wherein the ion implantation process includes a pre-amorphization implantation process.

16. The method of claim 14, wherein the thermal treatment process includes an annealing process.

17. The method of claim 14, wherein the thermal treatment process is conducted at a temperature of about 400˜900 degrees Celsius.

18. The method of claim 14, wherein the thermal treatment process is conducted for about 10 seconds to 2 hours.

19. The method of claim 14, wherein the semiconductor substrate is applicable for a P-type metal oxide semiconductor transistor, and the stress is a compressive stress.

20. The method of claim 19, wherein dopants used in the ion implantation process include carbon ions and the first epitaxial layer is a silicon-carbon layer.

21. The method of claim 19, wherein a dosage of dopants used in the ion implantation process is about 10¹⁴˜10¹⁶ cm⁻².

22. The method of claim 19, wherein implantation energy of the ion implantation process is about 1˜10 keV.

23. The method of claim 14, wherein the semiconductor substrate is applicable for an N-type metal oxide semiconductor transistor, and the stress is a tensile stress.

24. The method of claim 23, wherein dopants used in the ion implantation process include germanium ions, and the first epitaxial material layer is a silicon-germanium layer.

25. The method of claim 23, wherein a dosage of dopants used in the ion implantation process is about 10¹⁵˜5×10¹⁶ cm⁻².

26. The method of claim 23, wherein implantation energy of the ion implantation process is about 10˜40 keV.

27. The method of claim 14, wherein each source/drain region includes a doped region formed in the substrate and a second epitaxial material layer formed on the doped region.

28. The method of claim 27, wherein when the semiconductor device is a P-type metal oxide semiconductor transistor and the second epitaxial material layer is a silicon-germanium layer, and when the semiconductor device is an N-type metal oxide semiconductor transistor, the second epitaxial material layer is a silicon-carbon layer.

29. The method of claim 14, wherein the source/drain regions include a second epitaxial material layer formed in the substrate.

30. The method of claim 29, wherein when the semiconductor device is a P-type metal oxide semiconductor transistor, the second epitaxial material layer is a silicon-germanium layer, and when the semiconductor device is an N-type metal oxide semiconductor transistor, the second epitaxial material layer is a silicon-carbon layer.

31. The method of claim 14, wherein subsequent to the fabrication of the semiconductor device, a silicide layer is further formed on the gate structure and the two source/drain regions.

32. The method of claim 31, wherein the silicide layer includes a heat resistant metal silicide layer, and a material of the heat resistant metal silicide layer is selected from the group consisting of nickel, tungsten, cobalt, titanium, molybdenum, and platinum.

33. The method of claim 14, wherein a stress layer is formed to cover and in conformal to the semiconductor device and the substrate.

34. The method of claim 33, wherein a material that constitutes the stress (stress?) layer includes silicon nitride or silicon oxide.

35. The method of claim 33, wherein a doping process or an annealing process is performed on the stress layer to adjust a stress value of the stress layer.

36. The method of claim 33, wherein when the semiconductor device is a P-type metal oxide semiconductor transistor, the stress layer is a compressive stress layer, and when the semiconductor device is an N-type metal oxide semiconductor transistor, the stress layer is a tensile stress layer.
